(19) United States
(12) Patent Application Publication
(10) Pub. No.: US 2002/0002695 A1
(43) Pub. Date: Jan. 3, 2002

(54) Method and system for decoding

(76) Inventors: Frank Kschischang, Mississsauga (CA); Jeffrey P. Castura, Toronto (CA)

Correspondence Address: PATENT ADMINSTRATOR, KATTEN MUCHIN ZAVIS, SUITE 1600, 525 WEST MONROE STREET, CHICAGO, IL, 60661, US

(21) Appl. No.: 09/870,662

(22) Filed: Jun. 1, 2001

Related U.S. Application Data
(60) Provisional application No. 60/208,562, filed on Jun. 2, 2000.

(51) Int. Cl. H03M 13/03; H03M 7/00

(52) U.S. Cl. 714/794; 341/107

(57) ABSTRACT

A method and system for decoding is provided. In an aspect of the invention, an iterative method for decoding that utilizes a transformation of probability messages back and forth between formats that allow for the probability messages to be updated using only summation operations, rather than a combination of summation and product operations, thereby offering the ability to reduce the amount of hardware and/or software resources for decoding.

### PRIORITY CLAIM

This application claims priority from U.S. No. 60/208,562 filed Jun. 2, 2000, the contents of which are incorporated herein by reference.

### FIELD OF THE INVENTION

The present invention relates to decoders, and more particularly relates to decoders that can be used in a number of applications, such as any data storage or transmission application where the data can be corrupted by noise.

### BACKGROUND OF THE INVENTION

Coding schemes are well known and now widely implemented in many industrial and consumer applications. In general, coding techniques can greatly improve the successful storage or transmission of signals over a noisy channel, either wireless or wired. Turbo codes and convolutional codes are but two examples of extremely powerful coding schemes that are used in telecommunication systems. A detailed discussion of turbo codes can be found in the works of C. Berrou, such as “Near Shannon limit-error coding and decoding: Turbo-codes”, C. Berrou, A. Glavieux and P. Thitimajshima, Proceedings of IEEE International Conference on Communications, (Geneva, Switzerland), pp. 1074-1070, 1993, the contents of which are incorporated herein by reference.

From an implementation standpoint, however, coding schemes can present complex challenges, requiring a large number of processing cycles and/or memory. This is particularly the case with iterative decoding schemes. Such processor and/or hardware resources can be scarce, for example, when implementing a decoding scheme in a small cellular telephone or other type of wireless information appliance.

In order to assist in the implementation of coding schemes, prior art efforts utilize factor graphs to represent the coding matrix that underlies the particular coding scheme being implemented. Those of skill in the art will recognize that such coding matrices can be referred to as “generator matrices” or “parity check matrices”.

Factor graphs can be described as a composition of a series of check nodes and variable nodes that are interconnected by one or more lines. The number of check nodes, variable nodes, and their interconnections are drawn according to the composition of the coding matrix that the factor graph represents. Iterative decoding can thus be represented on the factor graph as the cycling of mathematical values, called “messages”, between the variable nodes and the check nodes along to the interconnecting lines. Each cycle represents an iteration performed during the decoding operation. Put in other words, iterative decoders can operate by passing messages back and forth along the lines that interconnect the check nodes and variable nodes, while new messages are calculated at both the variable nodes and the check nodes. Prior art decoding schemes typically involve a relatively simple summation calculation made at either the variable nodes or the check nodes, but then involve a relatively complicated, product calculation made at the opposite node. Unfortunately, the product calculation can be particularly difficult to implement in either hardware or software, requiring a large number of processor clock cycles and/or consuming a large portion of memory. For example, the Log Likelihood Ratio (“LLR”) calculation involves a simple summation calculation at the variable nodes but a complicated product calculation at the check nodes. In contrast, the Log Likelihood Difference Pair (“LLDP”) calculation, (also known as the Log-Magnitude-Difference calculation) involves complex product calculations at the variable nodes, but relatively simple summation calculations at the check nodes. These two calculations or representations are described in D. MacKay, “Good error-correcting codes based on very sparse matrices,” IEEE Transactions on Information Theory, volume 45. pp 399-431, March 1999; and, T. Richardson, R. Urbanke, M, Shokrollahi, “Design of Capacity-Approaching Irregular Low-Density Parity-Check Codes”, IEEE Transactions on Information Theory, February 2001, volume 47, Number 2, pp-619-637. The contents of both of these papers are incorporated herein by reference.

It is also known to make use of the duality of coding matrices to reduce complexity of calculations, without affecting the overall performance of the decoding. Such use of duality can be found in, for example, G. D. Forney, “Codes on graphs: Generalized state realizations”, IEEE Transactions on Information Theory, February 2001, volume 47, Number 2, pp. 520-548 , the contents of which is incorporated herein by reference. However, such prior art techniques that utilize duality lack efficiency in their transformations between one matrix and the other and have therefore been unsuitable for iterative decoding techniques such as used in association with factor graphs, as described above. Furthermore, Forney is considered by some to only be advantageous to a certain class of high rate codes—other types of codes are actually considered difficult to decode using Forney.

It is therefore desirable to provide a new method and system for decoding that provides simplified iterative calculations and therefore a more straightforward way of implementing decoding schemes in hardware and/or software.

### SUMMARY OF THE INVENTION

It is an object of the invention to provide a novel method and system for decoding that obviates or mitigates at least one of the above-identified disadvantages of the prior art.

In an aspect of the invention, there is provided a method for decoding comprising the steps of:

i) receiving a set of probability messages in a first format;

ii) updating the set of probability messages based on an operation that compares the set of probability messages with a first-set of code constraints;

iii) transforming the set updated at step ii) into a second format;

iv) updating the set transformed at step iii) based on an operation that compares the set of probability messages with a second-set of code constraints complementary to the first-set;

v) transforming the set updated at step iv) back into the first format;

vi) repeating steps ii)-v) on the set of probability messages transformed at v) until a desired level of decoding is reached; and,

vii) outputting the set of probability messages determined at step vi).

In a specific implementation of the foregoing aspect, the first-set is a set of variable node descriptors and the second-set is a set of check-node descriptors.

In another specific implementation of the foregoing aspect, the desired level of decoding is reached when step vi) is performed a predetermined number of times.

In a specific implementation of the foregoing aspect the desired level of coding is reached when step vi) is performed until the set of probability messages matches a known type of valid code.

In another aspect of the invention, there is provided a decoding comprising the steps of:

receiving a set of probability messages in a first format;

updating the set of probability messages based on an operation that compares the set of probability messages with a first-set of code constraints;

transforming the updated set into a second format;

updating the transformed set based on an operation that compares the set of probability messages with a second-set of code constraints complementary to the first-set;

transforming the updated set back into the first format;

repeating the foregoing steps after the receiving step on the set of probability messages until a desired level of decoding is reached; and,

outputting the set of probability messages once the desired level of decoding has been reached.

In another aspect of the invention, there is provided a system for decoding comprising an input device for receiving a set of probability messages in a first format. The system also comprises a first updating unit connected to the input device that is for updating the set of probability messages based on an operation that compares the set of probability messages with a first-set of code constraints. The system also includes a first transformation unit connected to the first updating unit and for transforming the updated set into a second format. The system also includes a second updating unit connected to the first transformation unit for the set of probability messages in the second-format with a second-set of code constraints complementary to the first-set. The system also includes a second transformation unit connected to the first updating unit and for transforming the set updated by the second updating unit back into the first format. The system also includes an output device connected to the second transformation unit and operable to determine if the set of probability messages has been decoded to a desired level. The output device is further operable to output the set of probability messages if the desired level of decoding has been achieved. The output device is further operable to return the set of probability messages back to the input device if desired level decoding has been achieved.

In a particular implementation of the foregoing aspect, the first-set is a set of variable node descriptors and the second-set is a set of check-node descriptors.

In a particular implementation of the foregoing aspect, the desired level of decoding is reached when the set has been updated a predetermined number of times.

In a particular implementation of the foregoing aspect the desired level of coding is reached when the set of probability messages matches a valid code word.

In a particular implementation of the foregoing aspect, there is provided a receiver operable to receive a channel carrying information intended for the receiver, the information being representable as probability messages, the receiver including the system for decoding according to the foregoing aspect. The receiver according can be incorporated into an information appliance. The information appliance can be a wireless telephone, a personal digital assistant, a pager, a web-browser, or the like.

The system cam be incorporated into a data storage device, and the channel interconnects the receiver and a data storage medium. The data storage medium can be magnetic or optical.

The probability messages can represent whether a given bit received over the channel is a “1” or a “0”, or the probability messages can represent a probability associated with a non-binary symbol received over the channel.

In another aspect of the invention, there is provided a system for decoding comprising an input means for receiving a set of probability messages in a first format and a transformation means operable to transform the probability messages between the first format and at least one additional format different from the first format. The system also includes an updating means for updating the probability messages according to each respective the format. The one or more formats are chosen according to a computationally desirable format to perform the updating. The system also includes an output means for outputting a decoded set of probability messages when a desired level of decoding has been achieved after at least one iteration of performing the transformations and the updates.

In a particular implementation of the foregoing aspect, the first format is in a log ratio representation and the second format is in a log magnitude difference representation.

In a particular implementation of the foregoing aspect, the computationally desirable formats allow the updating to be performed using a summation operation.

In a particular implementation of the foregoing aspect, the transformation means includes two transformation units, each operable to transform probability messages between a pair of the formats.

In a particular implementation of the foregoing aspect, the updating means includes two updating units, each operable to updating the probability messages in each the format.

A method and system for decoding is provided. In an aspect of the invention, there is provided an iterative method for decoding that utilizes a transformation of probability messages back and forth between formats that allow for the probability messages to be updated using only summation operations, rather than a combination of summation and product operations, thereby offering the ability to reduce the amount of hardware and/or software resources for decoding.

### BRIEF DESCRIPTION OF THE DRAWINGS

Preferred embodiments of the present invention will now be described, by way of example only, with reference to the attached Figures, in which:

FIG. 1 is a block diagram of a system for decoding in accordance with an embodiment of the invention;

FIG. 2 is an example of a coding matrix suitable for use with the system of FIG. 1;

FIG. 3 is a factor graph of the matrix shown in FIG. 2; and,

FIG. 4 is a flowchart of a method for decoding in accordance with another embodiment of the invention.

### DETAILED DESCRIPTION OF THE INVENTION

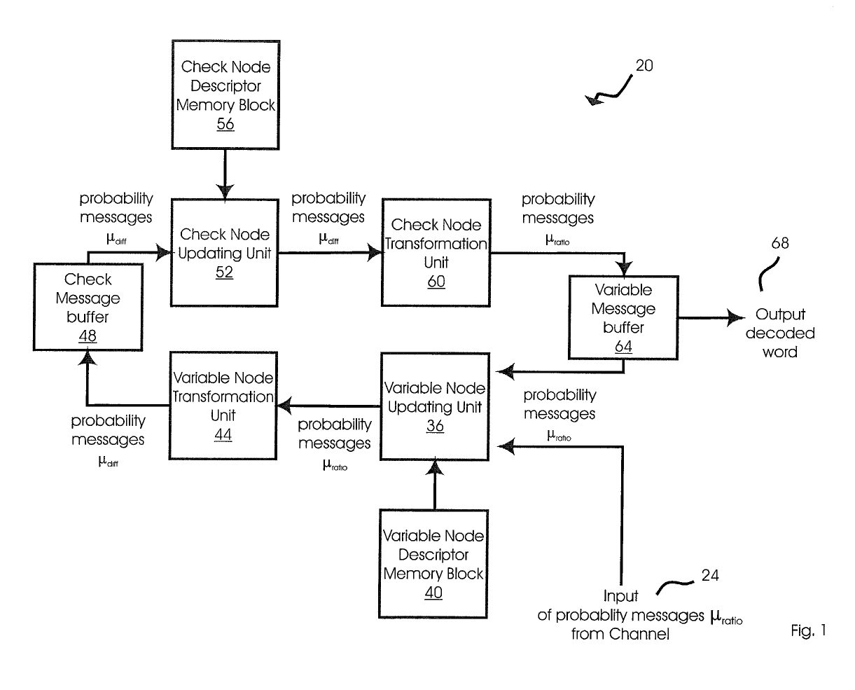

Referring now to FIG. 1, a system for decoding is indicated generally at 20. System 20 includes an input 24, which is operable to receive probability messages from a channel. While not shown in FIG. 1, the channel from which input 24 receives the probability messages is typically a wireless channel, such as that found in a CDMA or GSM cellular voice network and/or data network or the like. Those of skill in the art will recognize that the transmitter that emits the signal intended for reception by system 20 will encode the channel according to a coding matrix related to the matrix used for decoding by system 20. Thus, system 20 is typically incorporated into a receiver in a wireless network, such as the receiver of a wireless handset or wireless base station, as might be utilized in a CDMA or GSM cellular voice and/or data network or the like. However, in other embodiments of the invention, system 20 can be incorporated into wired channels, or data storage devices such as hard disc drives, where data stored on the storage device is transmitted over a storage device to the computer processing device accessing the storage device. Other applications of system 20 should now be apparent to those of skill in the art.

As used herein, the term “probability messages” means an array of data that is generated based on a coded word (or information of the like) received over the channel, whereby the string of data represents the probability of whether a given bit that is received over the channel is a “1” or a “0”. The probabilities can be represented as floating point value, a fixed point value or some other means. The probability messages conform with the particular coding matrix that underlies the coding scheme used to transmit the channel and the symmetric decoding scheme used by system 20.

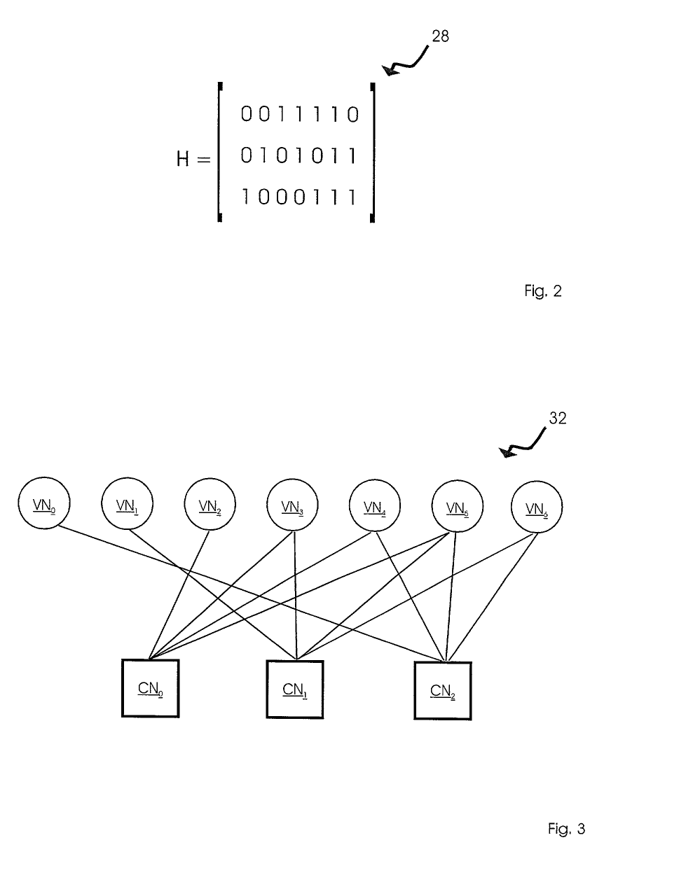

By way of example, FIG. 2 shows a coding matrix 28 that is suitable for use with system 20. Those of skill in the art will recognize that coding matrix 28 is a simple Hamming code. In general, those of skill in the art will recognize that the present invention has application to any type of generator matrix or parity check matrix, and that coding matrix 28 is merely an example for use in explaining the present embodiment.

By the same token, FIG. 3 shows coding matrix 28 represented in terms of a factor graph 32. Those of skill in the art will recognize that factor graph 32 has seven variable nodes VN₀, VN₁ . . . VN₆, one variable node VN for each column in matrix 28. Similarly, factor graph has three check nodes CN₀, CN₁ and CN₂, one check node CN for each row in matrix 28. Certain variable nodes VN and check nodes CN are interconnected by a line in correspondence with whether the intersection of a row and column of matrix 28 contains a “1”.

The probability messages processed by system 20 of FIG. 1 are represented in two formats, referred to herein as the log ratio representation and the log-magnitude-difference representation.

The log ratio representation can be written as show in Equation 1.

$${μ}_{ratio} ≡ log \frac{P [ 0 ]}{P [ 1 ]}$$

### Equation 1

The log magnitude difference representation is a pair of values, (s,r), the first defined over the set {−1,1} representing the sign bit, and the second over the set of positive real numbers such that:

μ_{diff}≡(sgn(P[0]−P[1]),|log|P[0]−P[1]||)

### Equation 2

In the present embodiment, the log ratio representation shown in Equation 1 is used to represent the probability messages associated with variable nodes VN, whereas the log magnitude difference representation shown in Equation 2 is used to represent the probability messages associated with check nodes CN. As used herein, probability messages in the format of Equation 1 are referred to as “probability messagesᵣₐₜᵢₒ”. Similarly, probability messages in the format of Equation 2 are referred to as “probability messages_{diff}”.

Thus referring again to FIG. 1, input 24 is operable to receive sampled information from the channel in the form of an array of probability messagesᵣₐₜᵢₒ, which are passed to a variable node updating unit 36. Variable node updating unit 36 can be implemented as either software or as a hardware device, as desired. Variable node updating unit 36 is operable to take probability messages in the format shown in Equation 1, (i.e. probability messages_{diff}) as received from input 24, and compare those probability messages with a first set of code constraints. In the present embodiment, the first set of code constraints are variable node descriptors, which are stored in a variable node descriptor memory block 40.

Memory block 40 can be implemented using any known computing storage means, such as random access memory whereby memory block 40 is loaded with variable node descriptors upon initialization of system 20. Memory block 40 can also be implemented as read only memory (“ROM”). Other computing storage means suitable for implementing variable node descriptor memory block 40 will occur to those of skill in the art. The variable node descriptors stored in memory block 40 conform with the underlying coding matrix used for system 20, such as the exemplary coding matrix 28 shown in FIG. 2, and therefore with its corresponding variable nodes VN shown in factor graph 32 of FIG. 3. Thus, variable node updating unit 36 utilizes memory block 40 to update probability messagesᵣₐₜᵢₒ received from input 24 according to the constraints variable node descriptors stored in memory block 40. The exact manner of updating is not particularly limited, and can be done according to known means of updating in the art. One suitable source of information for updating can be found in “Factor Graphs and the Sum-Product Algorithm”, F. Kschischang, B. Frey, H.-A. Loeliger pp. 498-519, IEEE Transactions on Information Theory, February 2001, volume 47, Number 2 the contents of which are incorporated herein by reference.

The probability messagesᵣₐₜᵢₒ that are updated at variable node updating unit 36 are passed to a variable node transformation unit 44, which is operable to convert probability messagesᵣₐₜᵢₒ into the format of probability messages_{diff}. In the present embodiment, variable node transformation unit 44 implements the function shown in Equation 3, in order to convert probability messagesᵣₐₜᵢₒ into the format of probability messages_{diff}.

$$Γ ( x ) ( s , r ) = ( sgn [ 2 ( \frac{{e}^{x}}{1 + {e}^{x}} ) - 1 ] , \vert log \vert 2 ( \frac{{e}^{x}}{1 + {e}^{x}} ) - 1 \vert \vert )$$

Where x is a probablity message in the format of μ_{diff}

### Equation 3

Equation 3 can be implemented in variable node transformation unit 44 as either a look-up table using the same type, (or indeed the very same), computing storage means as used to implement variable node descriptor memory block 40. If, for example, messages are stored as eight-bit values, then a look-up table of the size two-hundred-and-fifty-six bytes can be used to completely describe the function shown in Equation 3, and such a look-up table can be incorporated into variable node transformation unit 44 using any suitable computing storage means.

Alternatively, variable node transformation unit 44 can be implemented through the use of a combination of computer processing logic and computing storage means. For example, computing processing logic within transformation unit 44 can be used to determine the most significant bits of Equation 3, and the remaining least significant bits can be obtained by using a reduced look-up table implemented as a computing storage means. The computing processing logic can be implemented as either software, or hardware, as desired. Thus, the exact configuration of transformation unit 44 within system 20 can be chosen according to the constraints and/or features of the device or receiver within which system 20 is incorporated.

Variable node transformation unit 44 is thus operable to take a complete array of probability messagesᵣₐₜᵢₒ from variable node updating unit 36 and transform probability messagesᵣₐₜᵢₒ into the format of probability messages_{diff}. As each probability messages_{diff} is generated by transformation unit 44, it is passed to check message buffer 48 for temporary storage.

Check message buffer 48 can thus be implemented using any desired rewritable computer storage memory means, such as random access memory (RAM), or the like, enough to store a complete set of probability messages_{diff} Once check message buffer 48 is full the probability messages_{diff} stored therein are passed to a check node updating unit 52. (Typically, check message buffer 48 is considered full when a complete word of probability messages are buffered therein, however, while presently less preferred check message buffer 48 can be considered “full” when some amount of probability messages are stored therein that would be considered computationally useful to check node updating unit 52, the details of which will be discussed in greater detail below.)

Check node updating unit 52 can be implemented in substantially the same manner as variable node updating unit 36. More specifically, check node updating unit 52 can be implemented as either software or as a hardware device, as desired. Check node updating unit 52 is operable to take probability messages in the format shown in Equation 2, (i.e. probability messages_{diff}) as received from check message buffer 48, and compare those probability messages with a second set of code constraints. In the present embodiment, the second set of code constraints are check node descriptors, which are stored in a check node descriptor memory block 56.

Memory block 56 can be implemented using any known computing storage means, such as that previously described in relation to variable node descriptor memory block 40. If desired, memory block 56 and memory block 40 can be implemented on a single piece of hardware. Those of skill in the art should now recognize that, in the present embodiment, memory block 56 and memory block 40 can in fact be combined into a single memory block by making use of the complementary natures of variable node descriptors and check node descriptors. The check node descriptors stored in memory block 56 conform with the underlying coding matrix used for system 20, such as the exemplary coding matrix 28 shown in FIG. 2, and therefore with its corresponding check nodes CN shown in factor graph 32 of FIG. 3. Thus, check node updating unit 52 utilizes memory block 56 to update probability messages_{diff} received from check message buffer 48 according to the constraints of the check node descriptors stored in memory block 56. The exact manner of updating is not particularly limited, and can be done according to known means of updating in the art.

The probability messages_{diff} that are updated at check node updating unit 52 are passed to a check node transformation unit 60, which is operable to convert probability messages_{diff} into the format of probability messagesᵣₐₜᵢₒ. In the present embodiment, variable node transformation unit 44 implements the function shown in Equation 4, in order to convert probability messages_{diff} into the format of probability messagesᵣₐₜᵢₒ.

$${Γ}^{- 1} ( s , r ) ( x ) = log ( \frac{1 + {se}^{r}}{1 - {se}^{r}} )$$

Where (s,r) is the sign and magnitude of a probablity message in the form μ_{diff}

### Equation 4

Equation 4 can be implemented in check node transformation unit 60 as either a look-up table using the same type, (or indeed, the very same), computing storage means as used to implement variable node transformation unit 44. If, for example, messages are stored as eight-bit values, then a look-up table of the size two-hundred-and-fifty-six bytes can be used to completely describe the function shown in Equation 4, and such a look-up table can be incorporated into check node transformation unit 60 using any suitable computing storage means.

Those of skill in the art will now recognize that Equation 4 is essentially the inverse transform function of Equation 3, and that Equation 3 and Equation 4 make use of the duality properties of the underlying coding matrix, such as matrix 28 of FIG. 2. Thusly, it is typically expected that variable node transformation unit 44 and check node transformation unit 60 would be implemented in substantially the same manner, either through hardware or software, and utilizing computer processing logic and/or computing storage means.

Check node transformation unit 44 is thus operable to take a complete set of probability messages_{diff} from check node updating unit 52 and transform probability messages_{diff} into the format of probability messagesᵣₐₜᵢₒ. As each probability messageᵣₐₜᵢₒ is generated by transformation unit 60 , it is passed to a variable message buffer 64 for temporary storage.

Variable message buffer 60 can thus be implemented in substantially the same manner as check message buffer 48, as previously described.

However, in contrast to check message buffer 48, variable message buffer 48 further includes decision making means to determine whether the probability messages originally received at input 24 have been sufficiently decoded. If the probability messages originally received at input 24 have been sufficiently decoded, then the probability messagesᵣₐₜᵢₒ stored at variable message buffer 60 are passed to output 68 for further utilization by the receiver associated with system 20. However, if the decision making means within variable message buffer 64 determines that the probability messagesᵣₐₜᵢₒ stored at variable message buffer 60 have NOT been sufficiently decoded, then the probability messagesᵣₐₜᵢₒ stored therein are passed back to variable node updating unit 36 in the format of probability messagesᵣₐₜᵢₒ at which point the probability messages cycle again through system 20 until such time that the decision making means within variable message buffer 64 determines that the probability message probability messagesᵣₐₜᵢₒ have been sufficiently decoded. Such decision making means can be made using any suitable means. For example, the decision making means within variable message buffer 60 can require that the probability messages cycle a predetermined number of times through system 20. The decision making means within variable message buffer 60 could also require that the probability messages cycle through system 20 until a valid codeword is detected, in strict compliance with the underlying coding matrix, such as matrix 28 shown in FIG. 2. Other decision making criteria will occur to those of skill in the art and are within the scope of the invention.

In another embodiment of the invention, Equation 5 shows an equation which can be implemented in a variable node transformation unit 44, or the like, as either software or hardware, or used to generate a look-up table stored in transformation unit 44 that is derived from the equation shown in Equation 3.

$${μ}_{ratio}^{i} = {Γ}^{- 1} ( {\prod }_{x ∈ f ( i )} {s}_{{μ}_{diff}^{x}} , {\sum }_{x ∈ f ( i )} {r}_{{μ}_{diff}^{x}} )$$

Where:

i is the ith element of the variable node input array;

f (i) is the set of messages connecting to the node associated with i, excluding i itself

### Equation 5

According to the same embodiment, Equation 6 shows an equation which can be implemented in a check node transformation unit 60, or the like, as either software or hardware, or used to generate a look-up table stored in transformation unit 60 that is derived from the equation shown in Equation 4.

$${μ}_{diff}^{′} = Γ ( {μ}_{init}^{i} + {\sum }_{x ∈ f ( j )} {μ}_{ratio}^{x} )$$

Where:

j is the jth element of the check node input array;

f (j) is the set of messages connecting to the node associated with j, excluding j itself

### Equation 6

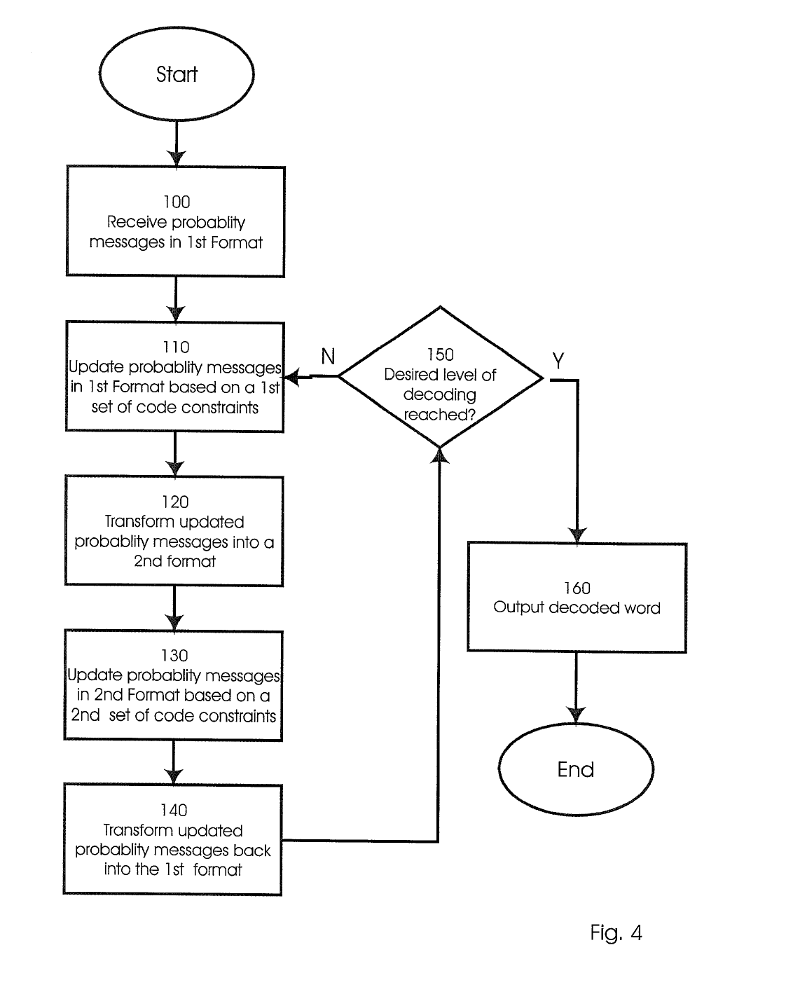

Referring now to FIG. 4, a flow-chart outlining a method for decoding is shown in accordance with another embodiment of the invention. The method of FIG. 4 outlines a number of steps which can be used to decode a single received codeword, and which can be repeated, or run in parallel, to decode a plurality of received codewords.

The method shown in FIG. 4 is an outline of a general set of process steps that can be performed using any desired configuration of computer hardware and/or software. Additionally, the steps shown in FIG. 4 need not be performed in the specific order shown. These configurations and variations are within the scope of the invention.

However, while not required, it is presently preferred to implement the method of FIG. 4 using system 20. Accordingly, in order to assist in the description of the method in FIG. 4, reference will be made to system 20, which is assumed to utilize an underlying coding matrix, such as, for example, coding matrix 28 and its associated factor graph 32.

Beginning at step 100, probability messages are received in a first format. In a presently preferred embodiment, the probability messages are received at input 24 as probability messagesᵣₐₜᵢₒ (i.e. variable node probability messages). However, it is to be understood that in other embodiments, such probability messages can be received in any suitable format.

At step 110, the probability messages received at step 100 are updated based on a first set of code constraints. In general, the first set of code constraints is complementary to the first format of the received probability messages. Thus, in a presently preferred embodiment, step 110 is performed variable node updating unit 36, which updates probability messagesᵣₐₜᵢₒ using a set of variable node descriptors as the first set of code constraints. As previously discussed, these variable node descriptors are retrieved by variable node updating unit 36 from variable node descriptor memory block 40. While not required, it is presently preferred, however, that the updating be performed using a summation operation, instead of a product operation. In general, the actual updating can be performed using any means known in the art, as previously discussed.

Next, at step 120, the updated probability messages are transformed into a second format that is a dual of the first format. In a presently preferred embodiment, the probability messagesᵣₐₜᵢₒ are transformed into the probability messages_{diff} The transformation is performed using variable node transformation unit 44, implementing Equation 3 or Equation 5, or the like, in order to transform probability messagesᵣₐₜᵢₒ into the format of probability messages_{diff}. In general it will be understood that any transform can be used to convert the probability messages from step 110 into a second format.

At step 130, the probability messages transformed at step 120 are updated based on a second set of code constraints. In general, the second set of code constraints is complementary to the second format of the probability messages. Thus, in a presently preferred embodiment, step 130 is performed check node updating unit 52, which receives a complete word of probability messages_{diff} that have been buffered in check message buffer 48. Check node updating unit 52 updates probability messages_{diff} using a set of check node descriptors as the second set of code constraints. As previously discussed, these check node descriptors are retrieved by check node updating unit 52 from check node descriptor memory block 56. While not required, it is presently preferred, however, that the updating be performed using a summation operation, instead of a product operation. Thus, it should now be apparent to those of skill in the art that the first format and second format of the probability messages are chosen so that the updating of those probability messages at step 110 and step 130 can be performed using summation operations, and accordingly the first set of code constraints and second set of code constraints associated with step 110 and step 130, respectively, are chosen to allow for the use of summation operations. (While presently much less preferred because it would require additional memory and/or processing resources, it is to be understood that the present embodiment could also be modified to allow the use of product operations at both steps 110 and 130).

Next, at step 140, the updated probability messages are transformed back into the first format. In a presently preferred embodiment, the probability messages_{diff} are transformed into the probability messagesᵣₐₜᵢₒ. The transformation is performed using check node transformation unit 60, implementing Equation 4 or Equation 6, or the like, in order to transform probability messages_{diff} into the format of probability messagesᵣₐₜᵢₒ. In general it will be understood that any transform can be used to convert the probability messages from step 130 back into the first format, and that typically, such a transform will be inverse to the transform used to transform from the first format into the second format.

The method then advances to step 150, where it is determined whether a desired level of decoding has been reached. This step can be accomplished using any desired criteria, such as whether a valid codeword that conforms with the underlying coding matrix has been achieved, or whether the steps 110-140 have cycled a predetermined number of times. If desired level of coding has not been reached, the method returns to step 110 utilizing the probability messagesᵣₐₜᵢₒ transformed at step 140. If, on the other hand, a desired level decoding has been reached, then the method advances to step 160 where the decoded word has been outputted. In a presently preferred embodiment, the decision making means to implement step 150 is incorporated into variable message buffer 64, which stores the complete array of probability messagesᵣₐₜᵢₒ transformed at step 140, by check node transformation unit 60, prior to making the determination at step 150. This array of probability messagesᵣₐₜᵢₒ is then passed either to variable node updating unit 36 if a desired level of decoding has not been reached, or it is outputted to output 68 if a desired level of decoding has been reached.

While the embodiments discussed herein are directed to specific implementations of the invention, it will be understood that combinations, sub-sets and variations of the embodiments are within the scope of the invention. For example, Equation 3 and Equation 4 can be substituted for other functions, inverse to the other, that achieve transformations in substantially the same manner.

Furthermore, while the specific embodiments discussed herein refer to probability messages which represent the probability of a given bit is either or a “1” or “0”, it should now be apparent to those of skill in the art that the present invention encompasses embodiments that include probability messages which represent probabilities associated with other types of symbols, in particular, non-binary symbols.

Additionally, while the embodiments discussed herein describe specific sequence or schedule, it is to be understood that these embodiments can be varied to utilize other schedules, and that such schedules are within the scope of the invention. As such, the term “schedule” is to be interpreted broadly, in that other variations of the invention could involve updating only part of a set of probability messages before transforming those probability messages into the other format. Typically, at least a “useful” portion of the set of probability messages would be updated before transforming those probability messages into the other format.

Furthermore, while not necessary, it is to be understood that system 20 can include further decision making functionality prior to input 24, so that input 24 only receives an initial probability message for decoding by system 20 if, somewhere prior to system 20, it has been determined that a valid codeword was not received over the channel.

The various elements shown in system 20 can be combined and/or implemented in a variety of ways using hardware and/or software, with a desired level of emphasis on either computer processing resources and/or memory resources. Such combinations and/or implementations are within the scope of the invention.

It is also to be understood that in embodiments discussed herein, the probability messages are both received and outputted in the variable node probability message format, yet in other embodiments, the probability messages can be received in the check node format and outputted in the check node format. Alternatively, the probability message can be received in one format, and outputted in the opposite format from the format in which the first probability message as was received. The choices for the format of the received probability message and the output probability message can be made according to the desired configuration of the receiver in which the various embodiments of the present invention are utilized.

It is also to be understood that the embodiments herein could be modified to include transformations between additional formats. For example, where three formats are chosen, there would be an update in the first format, a transformation into a second format, an update in the second format, a transformation into a third format, and an update in the third format. After the update in the third format, the decoded word could be outputted or, if was not sufficiently decoded, the updated probability messages in the third format could be transformed back into the first format for further updating. While such a use of more than two formats is presently less preferred, it is believed that more than two formats could be used to continue transforming the probability messages into formats so that the updating can be performed in a computationally desirable manner, such as using summing operations rather than product operations.

The present invention provides a novel method and system for decoding which transforms probability messages between back and forth between formats that allow the probability messages to be iteratively updated using computationally efficient, or otherwise desirable, operations. In certain aspects of the invention, such transformations utilize the duality properties of the underlying coding matrix used for encoding and decoding scheme of the channel. The iterative decoding includes transformations into computationally simple formats for updating. In this manner, implementations of decoders can be simplified, utilizing less hardware resources such as processing unit cycles and/or memory than found in certain other decoding schemes of the prior art, as found in for example, iterative decoders.

The above-described embodiments of the invention are intended to be examples of the present invention and alterations and modifications may be effected thereto, by those of skill in the art, without departing from the scope of the invention which is defined solely by the claims appended hereto.

We claim:

1. A method for decoding comprising the steps of:
i) receiving a set of probability messages in a first format;
ii) updating said set of probability messages based on an operation that compares said set of probability messages with a first-set of code constraints;
iii) transforming said set updated at step ii) into a second format;
iv) updating said set transformed at step iii) based on an operation that compares said set of probability messages with a second-set of code constraints complementary to said first-set;
v) transforming said set updated at step iv) back into said first format;
vi) repeating steps ii)-v) on said set of probability messages transformed at
v) until a desired level of decoding is reached; and,
vii) outputting said set of probability messages determined at step vi).

2. The method according to claim 1 wherein said first-set is a set of variable node descriptors and said second-set is a set of check-node descriptors.

3. The method according to claim 1 wherein said desired level of decoding is reached when step vi) is performed a predetermined number of times.

4. The method according to claim 1 wherein said desired level of coding is reached when step vi) is performed until said set of probability messages matches a valid code word.

5. A method for decoding comprising the steps of:
receiving a set of probability messages in a first format;
updating said set of probability messages based on an operation that compares said set of probability messages with a first-set of code constraints;
transforming said updated set into a second format;
updating said transformed set based on an operation that compares said set of probability messages with a second-set of code constraints complementary to said first-set;
transforming said updated set back into said first format;
repeating said foregoing steps after said receiving step on said set of probability messages until a desired level of decoding is reached; and,
outputting said set of probability messages once said desired level of decoding has been reached.

6. A system for decoding comprising:
an input device for receiving a set of probability messages in a first format;
a first updating unit connected to said input device and for updating said set of probability messages based on an operation that compares said set of probability messages with a first-set of code constraints;
a first transformation unit connected to said first updating unit and for transforming said updated set into a second format;
a second updating unit connected to said first transformation unit for said set of probability messages in said second-format with a second-set of code constraints complementary to said first-set;
a second transformation unit connected to said first updating unit and for transforming said set updated by said second updating unit back into said first format; and,
an output device connected to said second transformation unit and operable to determine if said set of probability messages has been decoded to a desired level, said output device further operable to output said set of probability messages if said desired level of decoding has been achieved, said output device further operable to return said set of probability messages back to said input device if desired level decoding has been achieved.

7. The system according to claim 1 wherein said first-set is a set of variable node descriptors and said second-set is a set of check-node descriptors.

8. The system according to claim 6 wherein said desired level of decoding is reached when said set has been updated a predetermined number of times.

9. The system according to claim 8 wherein said desired level of coding is reached when said set of probability messages matches a valid code word.

10. A receiver operable to receive a channel carrying information intended for said receiver, said information being representable as probability messages, said receiver including the system for decoding according to claim 8.

11. The receiver according to claim 10 wherein said channel is a wireless channel.

12. The receiver according to claim 10 wherein said receiver is incorporated into an information appliance.

13. The receiver according to claim 10 wherein said information appliance is a wireless telephone.

14. The receiver according to claim 10 wherein said information appliance is a pager.

15. The receiver according to claim 9 wherein said channel is a wired channel.

16. The receiver according to claim 15 wherein said receiver is incorporated into a data storage device, and said channel interconnects said receiver and a data storage medium.

17. The receiver according to claim 16 wherein said data storage medium is magnetic.

18. The receiver according to claim 16 wherein said data storage medium is optical.

19. The receiver according to claim 10 wherein said probability messages represent whether a given bit received over said channel is a “1” or a “0”.

20. The receiver according to claim 10 wherein said probability messages represent a probability associated with a non-binary symbol received over said channel.

21. A system for decoding comprising:
an input means for receiving a set of probability messages in a first format;
a transformation means operable to transform said probability messages between said first format and at least one additional format different from said first format.
an updating means for updating said probability messages according to each respective said format, said formats chosen according to a computationally desirable format to perform said updating;
an output means for outputting a decoded set of probability messages when a desired level of decoding has been achieved after at least one iteration of performing said transformations and said updates.

22. The system according to claim 20 wherein said first format is in a log ratio representation and said second format is in a log magnitude difference representation.

23. The system according to claim 20 wherein said computationally desirable formats allow said updating to be performed using a summation operation.

24. The system according to claim 20 wherein said transformation means includes two transformation units, each operable to transform probability messages between a pair of said formats.

25. The system according to claim 23 wherein said transformation means includes two updating units, each operable to updating said probability messages in each said format.

26. The system according to claim 20 wherein said first format can be represented according to the equation:
$${μ}_{ratio} ≡ log \frac{P [ 0 ]}{P [ 1 ]}$$
and said second format can be represented according to the equation:
μ_{diff}≡(sgn(P[0]−P[1]),|log|P[0]−P[1]||)
and a transformation from said first format to said second format can be performed according to the transformation:
$$Γ ( x ) ( s , r ) = ( sgn [ 2 ( \frac{{e}^{x}}{1 + {e}^{x}} ) - 1 ] , \vert log \vert 2 ( \frac{{e}^{x}}{1 + {e}^{x}} ) - 1 \vert \vert )$$
Where x is a probablity message in the format of μ_{diff}
and a transformation from said second format to said first format can be performed according to the transformation:
$${Γ}^{- 1} ( s , r ) ( x ) = log ( \frac{1 + {se}^{r}}{1 - {se}^{r}} )$$
Where (s,r) is the sign and magnitude of a probablity message in the form μ_{diff}

27. The system according to claim 20 wherein there are two of said formats and each format is the dual of the other format.
